(19) United States
(12) Patent Application Publication
(10) Pub. No.: US 2011/0133301 A1
(43) Pub. Date: Jun. 9, 2011

(54) WAFER LEVEL OPTICAL IMAGING APPARATUS

(75) Inventor: NAI-YUAN TANG, TAINAN (TW)

(73) Assignee: WISEPAL TECHNOLOGIES, INC., TAINAN (TW)

(21) Appl. No.: 12/630,776

(22) Filed: Dec. 3, 2009

(51) Int. Cl. H01L 31/14; H01L 31/0232

(52) U.S. Cl. 257/432; 257/E31.127; 257/E31.097

(57) ABSTRACT

A wafer level optical imaging apparatus includes a covering substrate that covers an imaging unit. A top shading layer is formed on a top surface of the covering substrate, and a bottom shading layer is formed on a bottom surface of the covering substrate.

### BACKGROUND OF THE INVENTION

1. Field of the Invention

The present invention generally relates to a wafer level module, and more particularly to a wafer level optical imaging apparatus that provides shading and prevents scattered light from being generated.

2. Description of Related Art

Wafer level optics (WLO) is a technique of fabricating miniaturized optics such as lens modules or camera modules at the wafer level using semiconductor techniques. The WLO technique is well adapted to mobile or handheld devices.

As shown in FIG. 1, a conventional optical imaging device 10 is commonly covered with a lens shade or hood 12 that is used to protect the optical imaging device 10 and provide a diaphragm (or iris) to the optical imaging device 10. However, for wafer level manufacturing or chip scale packaging, it is difficult to form a sufficiently small lens hood, or even more difficult to slice the wafer in order to obtain individual modules.

Further, with respect to either the wafer level optical imaging device or the traditional-scale optical imaging device, scattered light is usually generated within the field of view of the optical imaging device, leading to degradation of the imaging quality. However, few schemes have been designed to resolve this issue.

For the reason that these conventional optical imaging devices have fallen short of effectively solving the scattered light issue and have not economically provided a lens shade, a need has thus arisen to propose a novel scheme in order to resolve the problems mentioned above.

### SUMMARY OF THE INVENTION

In view of the foregoing, it is an object of the embodiment of the present invention to provide a wafer level optical imaging apparatus that not only provides a shading function but also prevents scattered light from being generated.

According to one embodiment, the wafer level optical imaging apparatus includes an imaging unit and a covering substrate that covers the imaging unit. The imaging unit includes a lens substrate with a lens formed on a surface of the lens substrate; an image sensor that converts light out of the lens substrate into electrical signals; and a number of spacers, wherein some of the spacers are adhered between the image sensor and the lens substrate and others are adhered between the lens substrate and the covering substrate. An opaque top shading layer is formed on a top surface of the covering substrate, and an opaque bottom shading layer is formed on a bottom surface of the covering substrate. According to one aspect of the embodiment, the top shading layer and the bottom shading layer have a top opening and a bottom opening respectively; and a dimension of the top opening is greater than a dimension of the bottom opening. Accordingly, the top opening and the bottom opening define a field of view that confines incoming light, which passes through the covering substrate and then reaches the lens substrate and the image sensor.

### BRIEF DESCRIPTION OF THE DRAWINGS

FIG. 1 shows a conventional optical imaging device covered with a lens shade;

FIG. 2 is a schematic cross section that illustrates a wafer level optical imaging apparatus having a covering substrate with top/bottom shading layers according to one embodiment of the present invention;

FIG. 3 is an exploded view of the covering substrate and top/bottom shading layers of FIG. 2; and

FIG. 4 illustrates an exemplary embodiment in the form of a wafer level camera module containing elements of the imaging unit of FIG. 2.

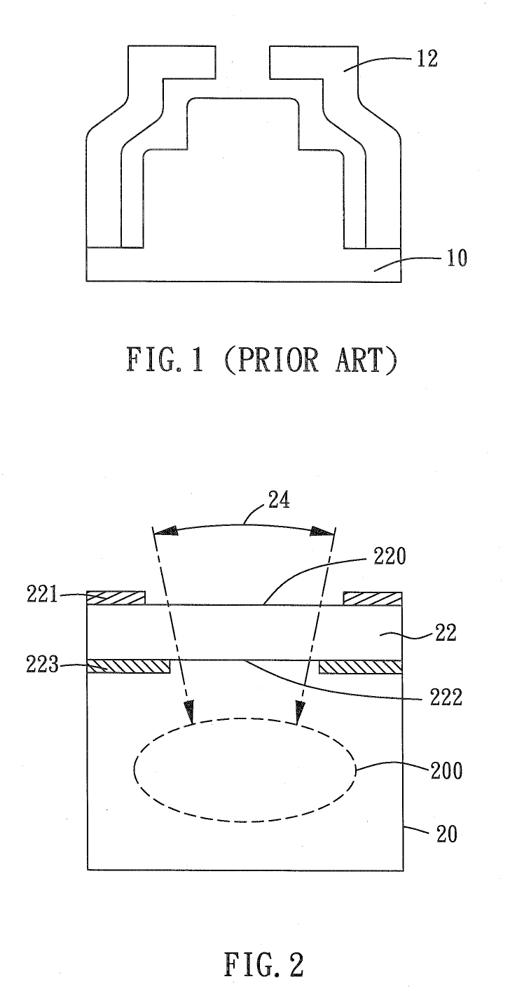

### DETAILED DESCRIPTION OF THE INVENTION

FIG. 2 is a schematic cross section illustrating a wafer level optical imaging apparatus according to one embodiment of the present invention. Although the present embodiment illustrated here is adapted to a wafer level camera, the embodiment of the present invention may be well adapted to other optical imaging apparatus.

In the embodiment, the wafer level optical imaging apparatus primarily includes an imaging unit 20 and a covering substrate 22. Specifically, the imaging unit 20 at least includes optics 200 (e.g., lens) which is schematically represented by a dashed oval in the figure. The covering substrate 22 may be, but is not limited to, a glass plate.

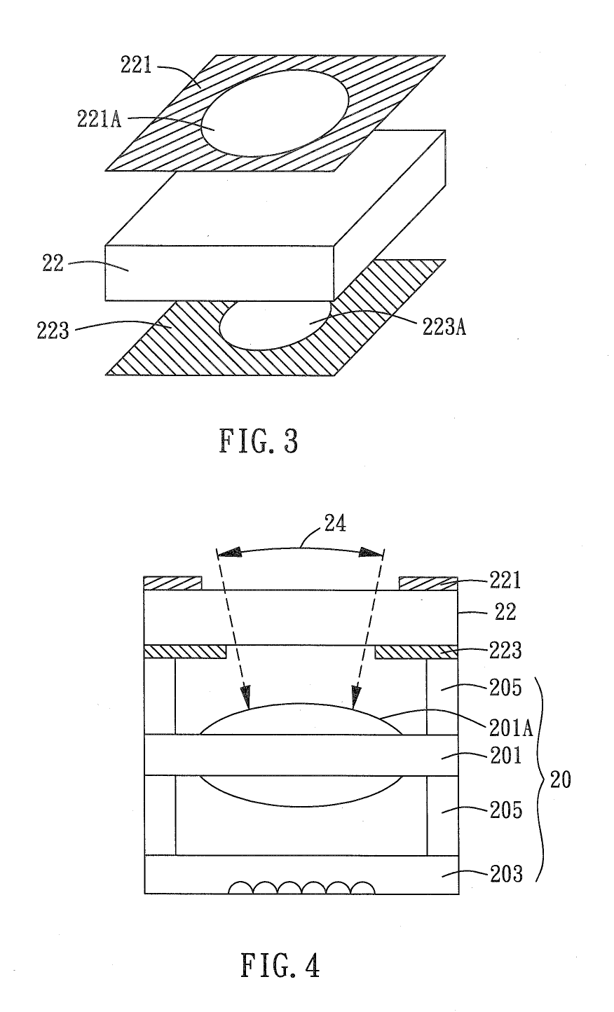

In the present embodiment, the top surface 220 and the bottom surface 222 of the covering substrate 22 are partially covered with an opaque top shading layer 221 and an opaque bottom shading layer 223 respectively. In this specification, the “top” is directed toward a light source, and the “bottom” is directed toward the imaging unit 20. FIG. 3 shows an exploded view of the covering substrate 22 along with the top/bottom shading layers 221/223. More specifically, the top shading layer 221 has a (top) circular opening 221A, and the bottom shading layer 223 also has a (bottom) circular opening 223A. In other embodiments, either or both of the patterned openings may not be limited to a circular configuration.

According to an aspect of the embodiment, the top opening 221A has a dimension (e.g., diameter) greater than the dimension of the bottom opening 223A. Consequently, as shown in FIG. 2, the (larger) top opening 221A and the (smaller) bottom opening 223A together define a field of view 24 that confines incoming light, passes through the covering substrate 22 and then finally reaches the imaging unit 20.

A feature of the embodiment comprises configuring the field of view 24 to allow passage only of required light and to block other light (e.g., unwanted light with angles larger than that defined by the field of view 24) from entering into the imaging unit 20. As a result, scattered light in the imaging unit 20 may be substantially reduced or even eliminated. In other words, the covering substrate 22 with the top/bottom shading layers 221/223 functions as a shade or hood to deter (e.g., prevent) generation of scattered light. Further, the covering substrate 22 may be used to protect the imaging unit 20 from being damaged. Moreover, in the embodiment, one or both of the top shading layer 221 and the bottom shading layer 223 may also function as diaphragm or iris.

FIG. 4 illustrates, as an exemplary embodiment, a wafer level camera module containing elements of the imaging unit 20. For brevity, only one module is depicted in the figure. In this exemplary embodiment, the imaging unit 20 primarily includes a lens substrate 201 with one or more lenses 201A formed on its surface, and an image sensor 203 such as a complementary metal oxide semiconductor (CMOS) image sensor or charge coupled device (CCD). The image sensor 203 converts the light out of the lens substrate 201 into electrical signals. Further, spacers 205 are adhered (e.g., by gluing) between the image sensor 203 and the lens substrate 201, and between the lens substrate 201 and the covering substrate 22. In the embodiment, the top shading layer 221 and the bottom shading layer 223 are respectively formed or deposited on the covering substrate 22, for example, by evaporation or sputtering. The deposited material may be, but is not limited to, chromium oxide. After the entire wafer is subjected to slicing, a number of wafer level camera modules therefore may be obtained.

Although specific embodiments have been illustrated and described, it will be appreciated by those skilled in the art that various modifications may be made without departing from the scope of the present invention, which is intended to be limited solely by the appended claims.

What is claimed is:

1. A wafer level optical imaging apparatus, comprising:
an imaging unit;
a covering substrate that covers the imaging unit;
a top shading layer formed on a top surface of the covering substrate; and
a bottom shading layer formed on a bottom surface of the covering substrate.

2. The apparatus of claim 1, wherein the imaging unit comprises optics.

3. The apparatus of claim 1, wherein the covering substrate comprises a glass plate.

4. The apparatus of claim 1, wherein the top shading layer is opaque and has a top opening, and the bottom shading layer is opaque and has a bottom opening, wherein the top opening and the bottom opening define a field of view that confines incoming light that passes through the covering substrate and then reaches the imaging unit.

5. The apparatus of claim 4, wherein a dimension of the top opening is greater than a dimension of the bottom opening.

6. The apparatus of claim 4, wherein the top opening is circular in shape, and the bottom opening is circular in shape.

7. The apparatus of claim 1, wherein the imaging unit comprises a lens substrate with a lens formed on a surface of the lens substrate.

8. The apparatus of claim 7, wherein the imaging unit further comprises an image sensor that converts light out of the lens substrate into electrical signals.

9. The apparatus of claim 8, wherein the imaging unit further comprises a plurality of spacers, wherein some of the spacers are adhered between the image sensor and the lens substrate and others are adhered between the lens substrate and the covering substrate.

10. The apparatus of claim 8, wherein the image sensor comprises a complementary metal oxide semiconductor (CMOS) image sensor or charge coupled device (CCD).

11. The apparatus of claim 1, wherein the top shading layer is deposited on the top surface of the covering substrate by evaporation or sputtering, and the bottom shading layer is deposited on the bottom surface of the covering substrate by evaporation or sputtering.

12. The apparatus of claim 11, wherein the top shading layer and the bottom shading layer comprise chromium oxide.

13. A wafer level optical imaging apparatus, comprising:
a lens substrate with a lens formed on a surface of the lens substrate;
an image sensor that converts light out of the lens substrate into electrical signals;
a covering substrate that covers the lens substrate;
a plurality of spacers, wherein some of the spacers are adhered between the image sensor and the lens substrate and others are adhered between the lens substrate and the covering substrate;
an opaque top shading layer formed on a top surface of the covering substrate; and
an opaque bottom shading layer formed on a bottom surface of the covering substrate;
wherein the top shading layer has a top opening, the bottom shading layer has a bottom opening, and a dimension of the top opening is greater than a dimension of the bottom opening;
wherein the top opening and the bottom opening define a field of view that confines incoming light, which passes through the covering substrate and then reaches the lens substrate and the image sensor.

14. The apparatus of claim 13, wherein the covering substrate comprises a glass plate.

15. The apparatus of claim 13, wherein the top opening is circular in shape, and the bottom opening is circular in shape.

16. The apparatus of claim 13, wherein the image sensor comprises a complementary metal oxide semiconductor (CMOS) image sensor or charge coupled device (CCD).

17. The apparatus of claim 13, wherein the top shading layer is deposited on the top surface of the covering substrate by evaporation or sputtering, and the bottom shading layer is deposited on the bottom surface of the covering substrate by evaporation or sputtering.

18. The apparatus of claim 17, wherein the top shading layer and the bottom shading layer comprise chromium oxide.
